(19) United States
(12) Patent Application Publication
(10) Pub. No.: US 2011/0049602 A1
(43) Pub. Date: Mar. 3, 2011

(54) NON-VOLATILE MEMORY SEMICONDUCTOR DEVICE AND MANUFACTURING METHOD THEREOF

(75) Inventor: Hidefumi NAWATA, Kawasaki-shi (JP)

(73) Assignee: KABUSHIKI KAISHA TOSHIBA, Tokyo (JP)

(21) Appl. No.: 12/815,767

(22) Filed: Jun. 15, 2010

(30) Foreign Application Priority Data
Aug. 25, 2009 (JP) 2009-194525

(51) Int. Cl. H01L 29/788; H01L 21/336

(52) U.S. Cl. 257/316; 438/593; 257/E21.422; 257/E29.3

(57) ABSTRACT

A gate insulating film layer, a floating gate electrode layer, an interelectrode insulating film layer, and a control gate electrode layer are stacked on a silicon substrate, and the control gate electrode film layer is etched to form a plurality of the control gate electrodes having the same width with the width of the memory cell. An arbitrary of the plurality of control gate electrodes is a transistor unit, and an interelectrode insulating film, a floating gate electrode, and a gate insulating film are formed in the transistor unit. In the transistor unit, a conductive material is buried into a contact hole to form a transistor, the contact hole is formed along the plurality of control gate electrodes.

### CROSS-REFERENCE TO RELATED APPLICATION

This application is based upon and claims the benefit of priority from prior Japanese Patent Application No. 2009-194525, filed on Aug. 25, 2009, the entire contents of which are incorporated herein by reference.

### BACKGROUND OF THE INVENTION

1. Field of the Invention

The present invention relates to a non-volatile memory semiconductor device and a manufacturing method thereof.

2. Background Art

To manufacture a non-volatile memory semiconductor device such as an NAND type flash memory, there is used a method of forming a plurality of memory cells in a memory cell array portion and a plurality of transistors (MOS transistors) in a transistor region portion such as a selective gate portion and a peripheral circuit portion together.

However, to form each of the memory cells and each of the transistors having different structures and pitches together, the manufacture of the non-volatile memory semiconductor device has an EI (Etching Interpoly) process for forming EI holes and a process for forming a mask pattern by a side wall remaining method while protecting a resist pattern over a predetermined region of the non-volatile memory semiconductor device with a protective film (which is disclosed in Japanese Patent Laid-Open No. 2007-305970, for example).

Further, the development of the non-volatile memory semiconductor device is expected to increase an operating speed and to reduce power consumption. Then, the non-volatile memory semiconductor device is shrinking, in particular, the memory cells is finer. The manufacture of the non-volatile memory semiconductor device is formed higher-precision and fine memory cells.

### SUMMARY OF THE INVENTION

According to an aspect of embodiments of the present invention, there is provided a manufacturing method of a non-volatile memory semiconductor device which has a first region having memory cells and a second region having transistors, comprising: in the first region and the second region will be formed, stacking a gate insulating film layer, a floating gate electrode layer, an interelectrode insulating film layer, a control gate electrode layer, and a first mask layer, on a silicon substrate, sequentially; and etching the control gate electrode layer to expose a surface of the interelectrode insulating film layer by using the first mask as mask, in order to form control gate electrodes having the same width with width of the memory cell, the first mask comprising a line portion having a width corresponding to the width of the memory cell; in the first region, etching the interelectrode insulating film layer and the floating gate electrode layer by using the first mask as mask; and in the second region, forming a third mask covering at a transistor unit determining a predetermined number of the control gate electrodes as the transistor unit; etching the interelectrode insulating film layer and the floating gate electrode layer by using the third mask as a mask; removing the first mask and the third mask; in the first region and the second region, forming an interlayer insulating film; etching the interlayer insulating film and etching the interelectrode insulating film and the upper portion of the floating gate electrode in the transistor unit to form a contact hole; and burying a conductive material into the contact hole, the conductive material making the control gate electrodes and the floating gate electrodes electrically conducts to form a gate electrode in which the control gate electrodes and the floating gate electrodes are electrically integrated.

According to another aspect of embodiments of the present invention, there is provided a non-volatile memory semiconductor device comprising: a memory cell array portion having memory cells, and a transistor region portion having transistors, wherein each of the memory cells has a first gate insulating film disposed on a silicon substrate, a first floating gate electrode disposed on the first gate insulating film, a first ineterelectrode insulating film disposed on the first floating gate electrode, and a first control gate electrode disposed on the first interelectrode insulating film, each of the transistors having a second gate insulating film disposed on the silicon substrate and a gate electrode disposed on the second gate insulating film, the gate electrode having a second floating gate electrode formed on the second gate insulating film, a second interelectrode insulating film formed on the second floating gate electrode, second control gate electrodes formed on the second interelectrode insulating film, and a conductive material, wherein the second control gate electrodes of the gate electrode having the same width as that of the first control gate electrode of the memory cell, and the conductive material being buried into a contact hole penetrated the second interelectrode insulating film and the second floating gate electrode disposed between a pair of adjacent second control gate electrodes so that the gate electrode are formed by the second floating gate electrode, the second control gate electrodes, and the conductive material.

### BRIEF DESCRIPTION OF THE DRAWINGS

FIGS. 1A and 1B are schematic plan views (partially) of a non-volatile memory semiconductor device of an embodiment of the present invention;

FIG. 2 is a schematic sectional view (partially) of a non-volatile memory semiconductor device of a first embodiment of the present invention;

FIGS. 3A and 3B are schematic process sectional views (1) for explaining a non-volatile memory semiconductor device manufacturing process of an embodiment of the present invention;

FIGS. 4A and 4B are schematic process sectional views (2) for explaining a non-volatile memory semiconductor device manufacturing process of an embodiment of the present invention;

FIG. 5 is a schematic process sectional view (3) for explaining a non-volatile memory semiconductor device manufacturing process of an embodiment of the present invention;

FIGS. 6A and 6B are schematic process sectional views (4) for explaining a non-volatile memory semiconductor device manufacturing process of an embodiment of the present invention;

FIGS. 7A and 7B are schematic process sectional views (5) for explaining a non-volatile memory semiconductor device manufacturing process of an embodiment of the present invention;

FIGS. 8A and 8B are schematic process sectional views (6) for explaining a non-volatile memory semiconductor device manufacturing process of an embodiment of the present invention;

FIGS. 9A and 9B are schematic process sectional views (7) for explaining a non-volatile memory semiconductor device manufacturing process of an embodiment of the present invention;

FIGS. 10A and 10B are schematic process sectional views (8) for explaining a non-volatile memory semiconductor device manufacturing process of an embodiment of the present invention;

FIGS. 11A and 11B are schematic process sectional views (9) for explaining a non-volatile memory semiconductor device manufacturing process of an embodiment of the present invention;

FIGS. 12A and 12B are schematic process sectional views (10) for explaining a non-volatile memory semiconductor device manufacturing process of an embodiment of the present invention; and

FIG. 13 is a schematic sectional view (partially) of the non-volatile memory semiconductor device of a modification example of the embodiment of the present invention.

### DETAILED DESCRIPTION OF THE INVENTION

Before describing an embodiment of the present invention, details in which the present inventor has made the present invention will be described.

First, a non-volatile memory semiconductor device manufacturing method of the related art will be briefly described. Here, this will be described by taking a NAND type flash memory manufacturing method as an example.

A NAND type flash memory has a memory cell array portion having memory cells, and a transistor region portion, such as a selective gate portion and a peripheral circuit portion, having transistors.

Each of the memory cells and each of the transistors in the NAND type flash memory of the related art, which are manufactured together, have the following structures.

Each of the transistors basically has the same stacked structure as that of each of the memory cells, in detail, a structure in which a gate insulating film, a floating gate electrode, an interelectrode insulating film, and a control gate electrode are successively stacked. In order to make each of the transistors has not the memory cell structure but the MOS transistor structure, after the interelectrode insulating film layer is stacked during the formation of the stacked structure, a process for forming holes (in this specification, hereinafter, these holes will be called EI (Etching Interpoly) holes) in the interelectrode insulating film layer is added, and then, the control gate electrode layer is stacked. In that case, the control gate electrodes are buried into the EI holes, thereby making the floating gate electrodes and the control gate electrodes electrically connect. In other words, the floating gate electrodes and the control gate electrodes electrically connected by using the control gate electrodes in the EI holes, thereby making each of the floating gate electrodes and each of the control gate electrodes electrically integrated, to form each of gate electrodes in the MOS transistor structure.

Accordingly, the NAND type flash memory of the related art has the EI process for forming the EI holes in order to manufacture each of the memory cells and each of the transistors together.

Further, in the NAND type flash memory manufacturing method, each of the memory cells is formed so as to have a pitch finer than the limit of the exposure accuracy of the lithography method. Accordingly, a mask pattern for forming such fine memory cell is formed by a method called a side wall remaining method.

The side wall remaining method is as follows.

A mask pattern including a resist film and having a rough pitch is formed over a processed substrate by the lithography method.

An underlayer for forming the mask pattern (e.g., silicon nitride film) is etched by using the resist film in order to form the mask pattern. The mask pattern has in itself a width and a pitch corresponding to the desired pitch. A side wall film (e.g., a silicon oxide film) is stacked so as to cover at least the side walls of the mask pattern. The side wall film is etched, whereby the etched side wall films remain only on both sides of the mask pattern so that the mask pattern is sandwiched between the side wall films from both sides. At the same time, a gap with the desired pitch is formed between the adjacent side wall films. The mask pattern is then selectively removed so that only the side wall films remain over the processed substrate. Thus, the side wall films are aligned over the processed substrate at the desired pitch. In other words, the side wall films are formed over the processed substrate, as mask pattern having a pitch finer than that of the initially formed mask pattern, that is, a pitch corresponding to the fine memory cell.

To form a mask pattern having a finer pitch, a slimming method (process) which reduces the width of a mask pattern having a rough pitch to stack the side wall film can be added to the side wall remaining method.

The side wall remaining method has the advantage that the mask pattern having a pitch finer than the limit of the exposure accuracy of the lithography method can be uniformly and simply formed on the entire surface of the processed substrate.

By forming each of the memory cells and each of the transistors together by using the mask pattern formed by the side wall remaining method, the mask pattern can obtain each of the memory cells in the desired shape. However, each of the transistors in the desired shape cannot obtain with the mask pattern due to the fine pitch. In other words, to obtain each of the transistors in the desired shape, a mask pattern is a rough pitch.

Accordingly, in the NAND type flash memory manufacturing method of the related art, to form each of the memory cells and each of the transistors together, a method of forming a mask pattern using the side wall remaining method by covering the transistor region portion with the protective film is adopted. Such process for forming the protective film is called a GP process.

The side wall remaining method to which the GP process is added will be described below.

The above side wall remaining method is used to form mask pattern including fine side wall films in the memory cell array portion and the transistor region portion. At this time, the mask pattern sandwiched between the side wall films is in the remaining state. A gap having a predetermined width exists in the mask pattern while the mask pattern is sandwiched between the side wall films from both sides of the mask pattern.

In the transistor region portion, the protective film (e.g., resist film) is stacked so as to cover the upper surfaces of the mask pattern and the upper surfaces of the side wall films and to bury the gap in the mask pattern sandwiched between the side wall films.

The mask pattern is selectively removed while the protective film is stacked. Thus, the mask pattern is removed in the memory cell array portion while the mask pattern covered with the protective film is not removed in the transistor region portion.

When the protective film is removed, fine mask pattern including only the side wall films appear in the memory cell array portion. And rough mask pattern including the mask pattern and the side wall films integrally configure a rough pitch appear in the transistor region portion.

By the above method, the mask pattern having appropriate pitches for the memory cell array portion and the transistor region portion, respectively, can be manufactured. Using the mask pattern, the memory cell and the transistor in the desired shape can be formed together.

As described above, the present inventor has considered whether higher-precision and fine memory cells and high-performance transistors can be formed by the NAND type flash memory manufacturing method. In addition, the present inventor has considered a method of shortening the manufacturing process by integrating a plurality of processes into one process. This is because the manufacturing time and the manufacturing cost of the NAND type flash memory are reduced.

Further, the present inventor has found that when the mask pattern formed by the side wall remaining method with the GP process are used to form each of the memory cells and each of the transistors together, the processing accuracy of the fine memory cell is difficult. The mask pattern formed by the side wall remaining method with the GP process are mask pattern having a non-uniform pitch so as to have a fine pitch in the memory cell array portion, but to have a rough pitch in the transistor region portion. Typically, when such mask pattern having a non-uniform pitch are used for processing, the processing accuracy of such mask pattern is lower than that of the mask pattern having a uniform pitch.

Accordingly, the present inventor devised the present invention which is able to have each transistor of a structure different from that of the related art to form higher-precision and fine memory cells and high-performance transistors and integrate a plurality of processes into one process.

In detail, the structure of the transistor according to the present invention is different from that of the transistor of the related art as follows.

The transistor of the present invention does not have the EI holes unlike the related art. In place of that, the transistor of the present invention has a conductive material (contact body portion). The conductive material penetrates from an interconnecting layer through an insulating film such as a TEOS film and an SiN film to a control gate electrode, and furthermore, the conductive material comprises the portions of the conductive material (contact leg portion). The portions of the conductive material penetrated through an interelectrode insulating film formed under the control gate electrode to a floating gate electrode. In other words, in place of the EI holes, the control gate electrode and the floating gate electrode are electrically connected by the conductive material so as to be an electrically integrated gate electrode.

In addition, the present inventor has made the transistor of the present invention have a structure in which the area of the conductive material contacted with the control gate electrode and the floating gate electrode is increased. In detail, the transistor of the present invention has a plurality of the conductive material portions (contact leg portions) penetrated through the interelectrode insulating film and connecting the control gate electrode and the floating gate electrode according to the size of the transistor. Thus, the area of the conductive material contacted with the control gate electrode and the floating gate electrode is increased to reduce the resistance between the control gate electrode and the floating gate electrode to make the transistor high-performance. Such shape is formed using the control gate electrode processed with high precision. Thus, the conductive material can be formed with high precision.

Each of the transistors has such structure so that the EI process for forming the EI holes to electrically connect the floating gate electrode and the control gate electrode, which has been performed in the NAND type flash memory manufacturing method of the related art, need not be performed. In case the conductive material (contact body portion) connecting the interconnect and the control gate electrode is formed, in place of the EI hole, the conductive material portion (contact leg portion) electrically connecting the control gate electrode and the floating gate electrode can also be formed at the same time. According to the present invention, a plurality of processes can be integrated into one process.

In the NAND type flash memory manufacturing method according to the present invention, mask pattern having a uniformly fine pitch are formed once by the side wall remaining method, and using the mask pattern, each memory cell and each transistor are processed together. Thus, the fine memory cell can be processed with higher precision.

An embodiment of the present invention will be described.

First, the plane structure of an NAND type flash memory of the present invention will be briefly described.

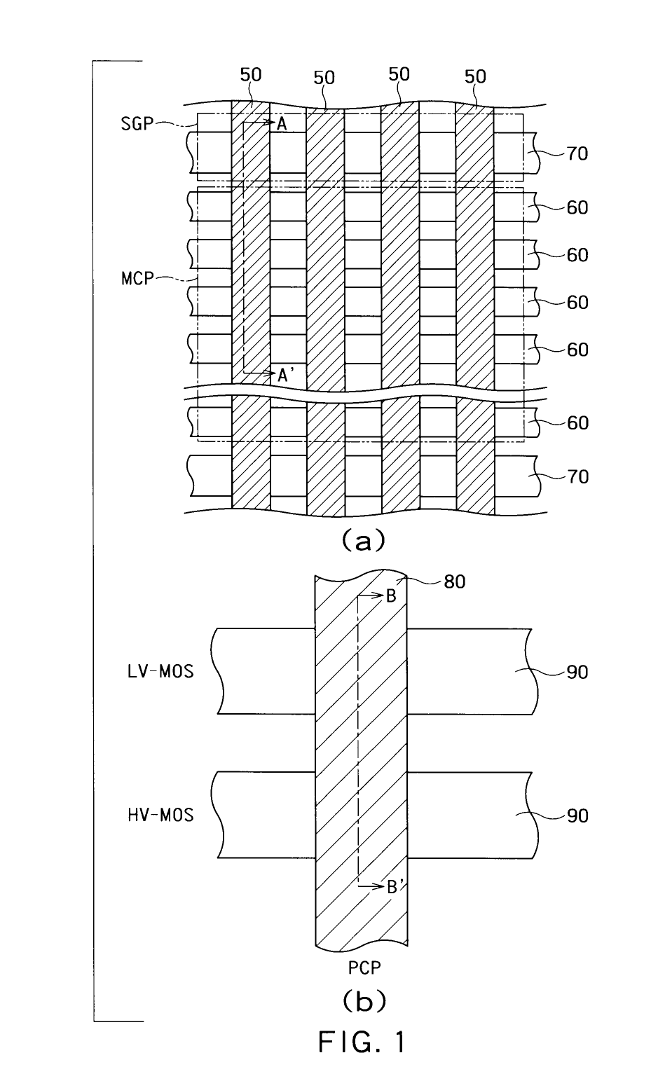

The NAND type flash memory of the present invention has a memory cell array portion MCP, a selective gate portion (transistor region portion) SGP shown in FIG. 1A, and a peripheral circuit portion (transistor region portion) PCP shown in FIG. 1B.

In more detail, bit lines 50 are formed along an up-down direction of the sheet of FIG. 1A in the memory cell array portion MCP of the NAND type flash memory of the present invention. The bit lines 50 are arranged at a fixed pitch in a horizontal direction of the sheet and are parallel with each other. Word lines 60 are formed so as to be orthogonal to the bit lines 50 as seen in a plane. A memory cell MC is disposed in each portion in which each of the bit lines 50 and each of the word lines 60 cross in three dimensions. In other words, the memory cells MC are arranged in a matrix in the memory cell array portion MCP of the NAND type flash memory.

The selective gate portion SGP is arranged on at least one end side of the memory cell array portion MCP. Transistors (MOS transistors) T are disposed in the selective gate portion SGP. Each of the transistors T is connected to the plurality of corresponding memory cells MC. Each of the transistors T is connected to the transistor T adjacent thereto by a selective gate line 70 formed so as to be orthogonal to the bit lines 50 seen in a plane.

The peripheral circuit portion PCP is arranged around the memory cell array portion MCP and the selective gate portion SGP. The peripheral circuit portion PCP has the transistors (MOS transistors) T. In detail, as shown in FIG. 1B, an element region 90 and a gate line 80 are arranged in the peripheral circuit portion PCP. A gate electrode (the control gate electrode and the floating gate electrode) is disposed at their cross point. A source-drain diffusion layer is disposed over the surface of the element region 90 on both sides of the gate electrode so as to sandwich the gate electrode. The transistors T are an HV-MOS (high-voltage driven MOS transistor) transistor and an LV-MOS (low-voltage driven MOS transistor) transistor whose operating voltage is lower than that of the HV-MOS.

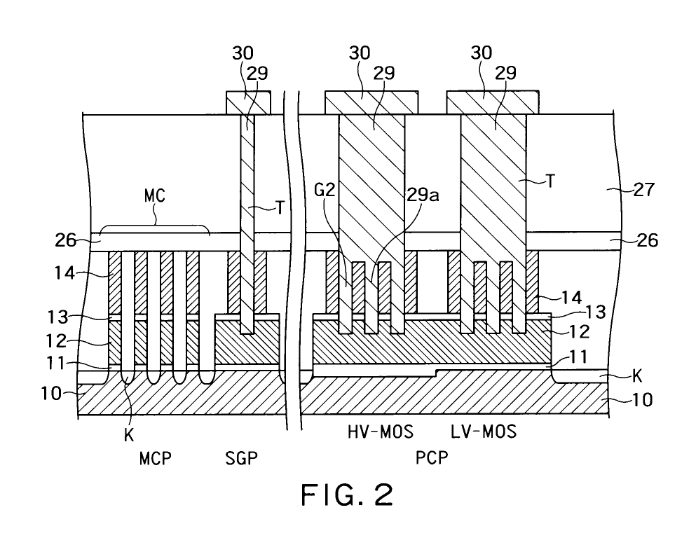

The sectional structure of the NAND type flash memory of the present invention will be described using FIG. 2. FIG. 2 is a schematic sectional view taken along lines A-A′ of FIG. 1A and B-B′ of FIG. 1B and shows the sectional structure of the NAND type flash memory of the present invention.

Each of the memory cells MC of the memory cell array portion has, over a silicon substrate 10, a gate insulating film (silicon oxide film) (a first gate insulating film) 11, a floating gate electrode (polysilicon film) 12, an IPD (Inter poly Dielectric) film (silicon oxide film) 13 as an interelectrode insulating film, and a control gate electrode (polysilicon film) 14.

As in the above memory cell MC, each of the transistors T of the selective gate portion SGP and the peripheral circuit portion PCP has a gate insulating film (a second gate insulating film) 11, a floating gate electrode 12, an IPD film 13, and a control gate electrode 14.

A silicon oxide film (interlayer insulating film) 25 is formed so as to cover the gate insulating film 11, the floating gate electrode 12, the IPD film (interelectrode insulating film layer) 13, and the control gate electrode 14 provided in each of the memory cells MC and each of the transistors T. A SiN film 26 and a TEOS (Tetraethoxysilane) film 27 are formed over the silicon oxide film 25.

Each of the transistors T has a conductive material 29 penetrated through the TEOS film 27, the SiN film 26, the control gate electrode 14, and the IPD film 13 to the floating gate electrode 12.

A portion (contact leg portion) of the conductive material 29 penetrated through the IPD film 13 and connecting the control gate electrode 14 and the floating gate electrode 12 is configured with a plurality of portions according to the size of the transistor.

In other words, the control gate electrodes 14 provided in each of the transistors T have the same width of that of the control gate electrodes 14 in the memory cell array portion MCP. Further, the conductive material 29 is buried into a contact hole penetrated from the control gate electrode 14 through the IPD film 13 to the floating gate electrode 12 along the gap between the adjacent control gate electrodes 14. The conductive material 29 may be an electrically conductive film having a resistivity lower than that of the control gate electrode 14 including a polysilicon film, e.g., a tungsten film.

Thus, the control gate electrode 14 and the floating gate electrode 12 are electrically conductive so as to be the electrically integrated gate electrode. In addition, the resistance between the control gate electrode and the floating gate electrode can be reduced, thereby making the transistor high-performance.

A diffusion layer K as a source/drain region of the memory cell transistors and the transistors T are formed in the silicon substrate 10 adjacent to the floating gate electrode 12.

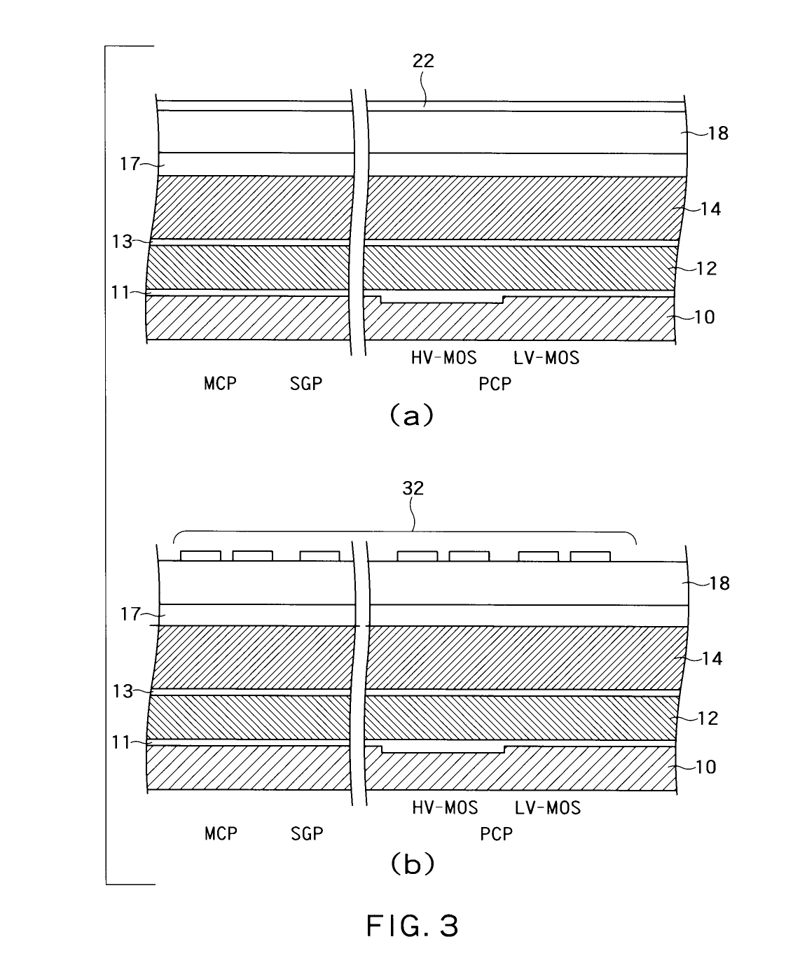

An NAND type flash memory manufacturing method of the present invention will be described with reference to FIGS. 3A to 12B.

FIGS. 3A to 12B show cross sections taken along lines A-A′ of FIG. 1A and B-B′ of FIG. 1B, that is, correspond to FIG. 2.

As shown in FIG. 3A, the gate insulating film (silicon oxide film) 11, the floating gate electrode (polysilicon film) 12, the IPD film (silicon oxide film) 13, the control gate electrode (polysilicon film) 14, a SiN film 17, a forming mask film (TEOS (Tetraethoxysilane) film) 18, and a first resist film 22 are successively stacked on the silicon substrate 10. To improve the durability of the first resist film 22 against etching, an SOG (Spin on Glass) film can also be stacked. The film thickness of the gate insulating film 11 of the region formed with the HV-MOS transistor is larger than that of other regions.

As shown in FIG. 3B, the first resist film 22 is exposed to form first resist pattern 32.

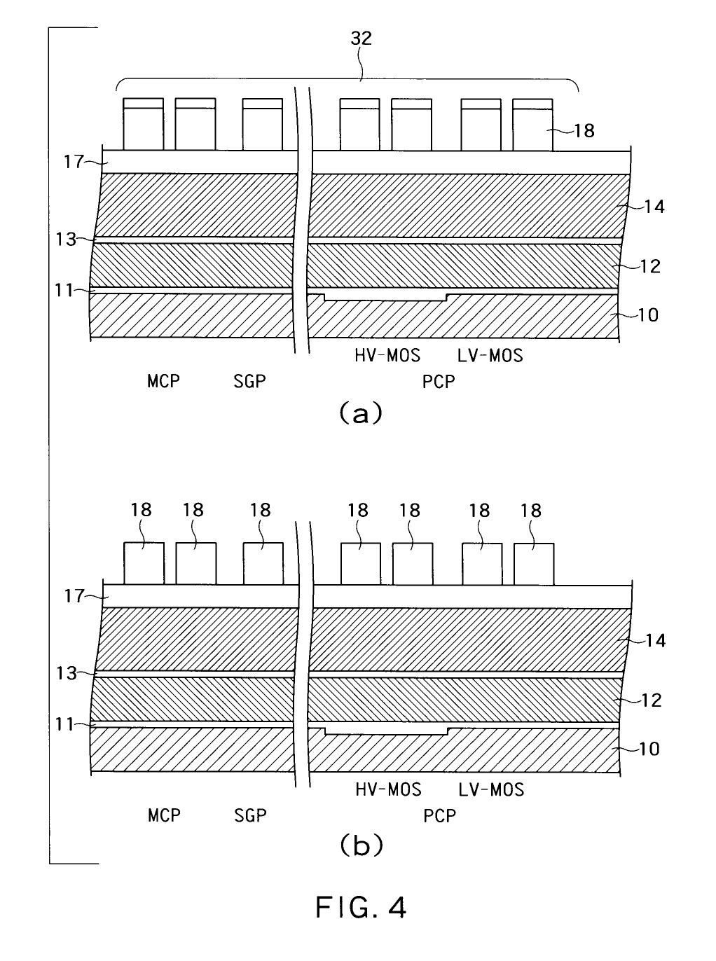

With the first resist pattern 32 as masks, the forming mask film 18 is etched by RIE (Reactive Ion Etching). As shown in FIG. 4A, pattern in which the forming mask film 18 are arranged along the first resist pattern 32 are formed.

As shown in FIG. 4B, the first resist pattern 32 is removed. Thus, the forming mask film 18 remains as stripe pattern.

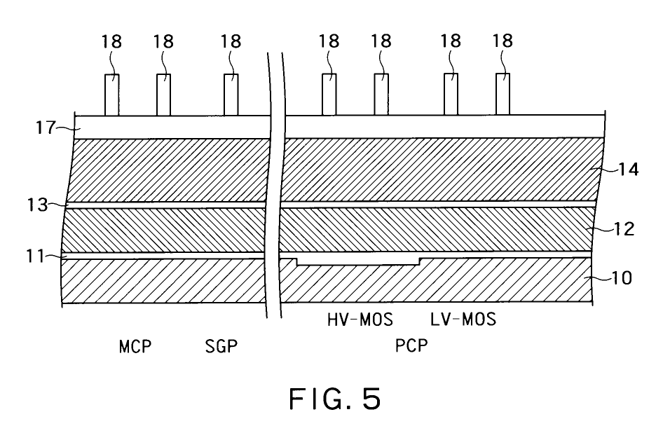

A slimming method is then performed. As shown in FIG. 5, the forming mask film 18 is selectively slimmed, for example, using wet etching. In other words, the width of the pattern of the forming mask film 18 is smaller than that of the first resist pattern 32.

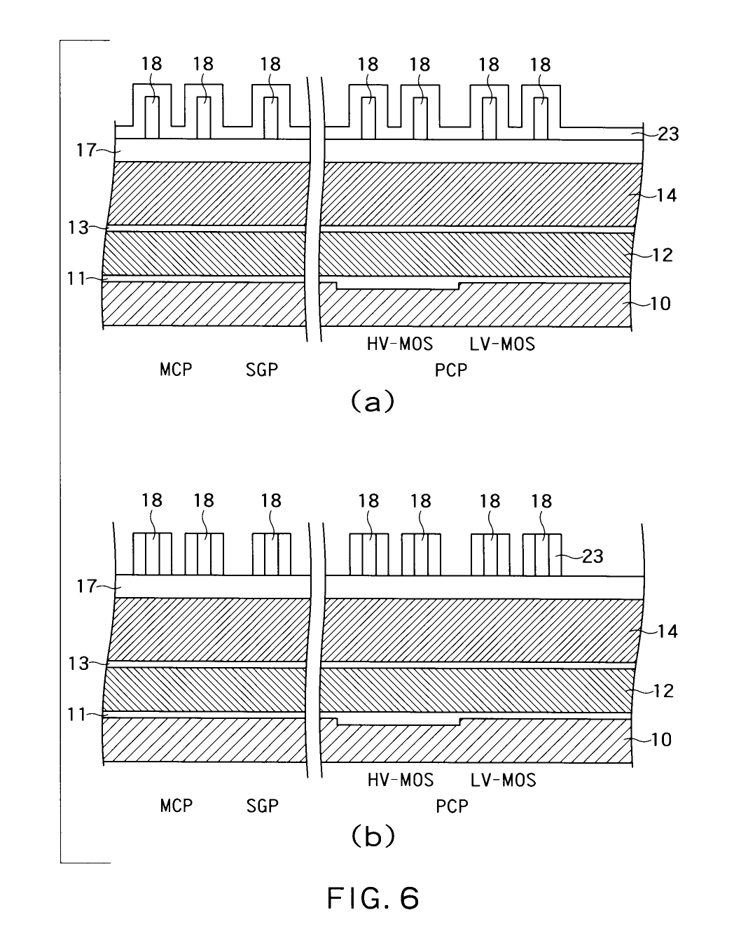

To form fine side wall film mask pattern 33, the side wall remaining method is performed. In detail, as shown in FIG. 6A, a side wall film (polysilicon film) 23 is formed so as to cover the upper surfaces and the side surfaces of the forming mask film 18. The side wall film 23 configures the fine side wall film mask pattern (first masks) 33.

As shown in FIG. 6B, in order to remain only the portions of the side wall film 23 on both sides of the forming mask film 18, the side wall film 23 are etched by RIE. The upper surfaces of the forming mask film 18 are exposed, and the upper surface of the SiN film 17 is partially exposed.

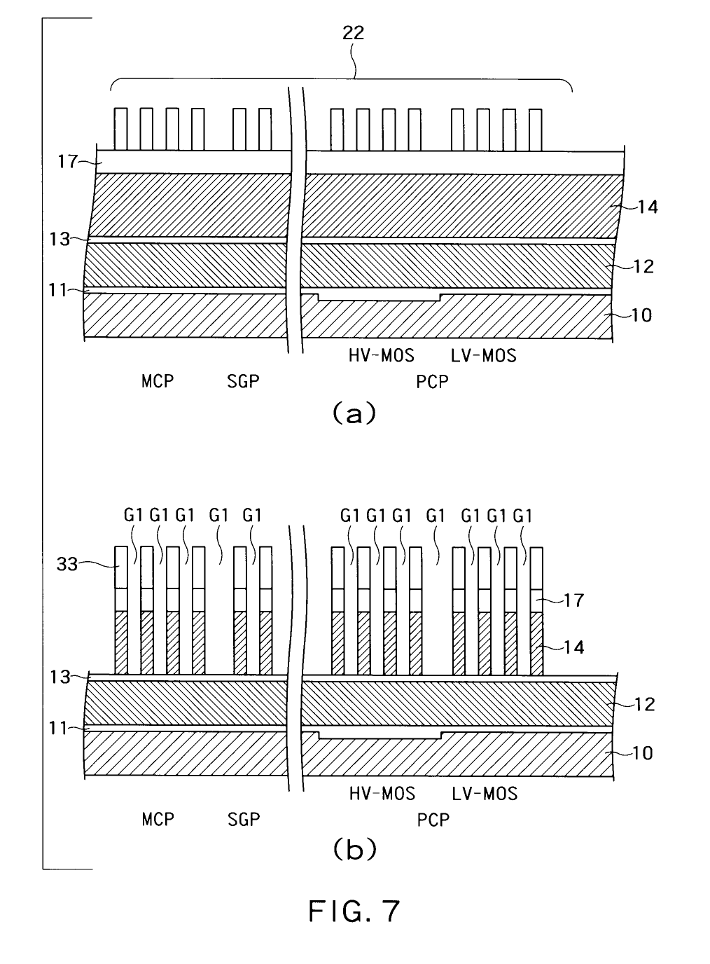

As shown in FIG. 7A, the forming mask film 18 sandwiched between the side wall films 23 are selectively removed, for example, by wet etching or RIE. The side wall films 23 are aligned in a stripe manner at the desired pitch over the SiN film 17 to form the fine side wall film mask pattern (first masks) 33 on the whole. In detail, the mask pattern 33 has lines corresponding to the width of the finally formed memory cell MC.

As shown in FIG. 7B, with the side wall film mask pattern 33 as masks, the SiN film 17 and the control gate electrode 14 are successively etched, for example, by RIE. Accordingly, grooves G1 extended from the side wall film mask pattern 33 to the upper surface of the IPD film 13, having the same width, and aligned at the same pitch are formed. The control gate electrodes 14 separated by the grooves G1 have the same width and are aligned. Using the IPD film 13 as a stopper, the control gate electrodes 14 can be reliably separated by the grooves G1.

In order to perform etching at a fine and uniform width over the entire surface of the control gate electrodes, the control gate electrode 14 and the like can be etched with higher precision than etching at a non-uniform width, which is performed in the NAND type flash memory manufacturing method of the related art. The groove G1 between the memory cell array portion MCP and the selective gate portion SGP may be larger than the groove G1 between the memory cell array portions MCP or the groove G1 between the selective gate portions SGP. The groove G1 between the region formed with the HV-MOS transistor and the region formed with the LV-MOS transistor may be larger than the groove G1 in the region formed with the HV-MOS transistor or the groove G1 in the region formed with the LV-MOS transistor.

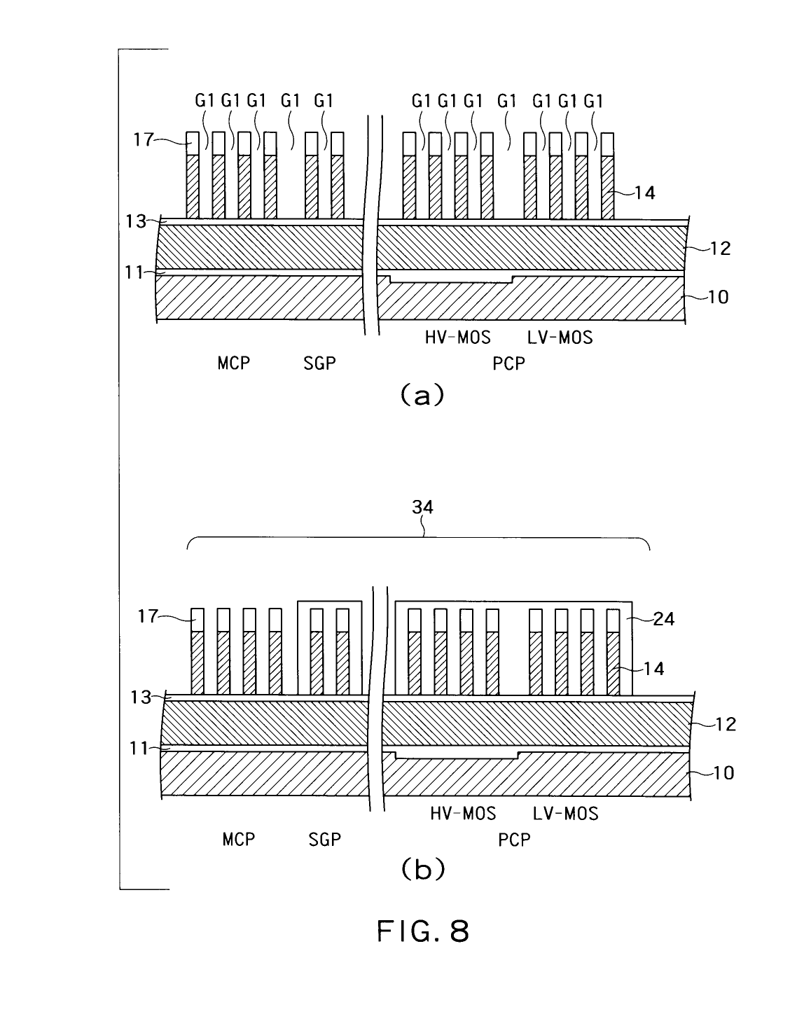

As shown in FIG. 8A, the side wall film mask pattern 33 is removed.

As shown in FIG. 8B, in the selective gate portion SGP and the peripheral circuit portion PCP, according to the size of each of the transistors T to be finally obtained, a second resist film (buried resist/a third mask) 24 is buried into a predetermined groove G1. Thus, in the memory cell array portion MCP, the control gate electrodes 14 are integrated in a pillar manner to form a pattern (a second mask) having a fine pitch corresponding to the size of each of the memory cells. In the selective gate portion SGP and the peripheral circuit portion PCP, the control gate electrodes 14 integrated in a pillar shape are covered with the second resist film to become mask sections of a transistor unit according to the size of each of the transistors to be finally obtained. A pattern (a third mask) of each of the gate electrodes in which these mask sections have a rough pitch is formed. The two patterns (the second mask and the third mask) having different pitches are mask pattern 34.

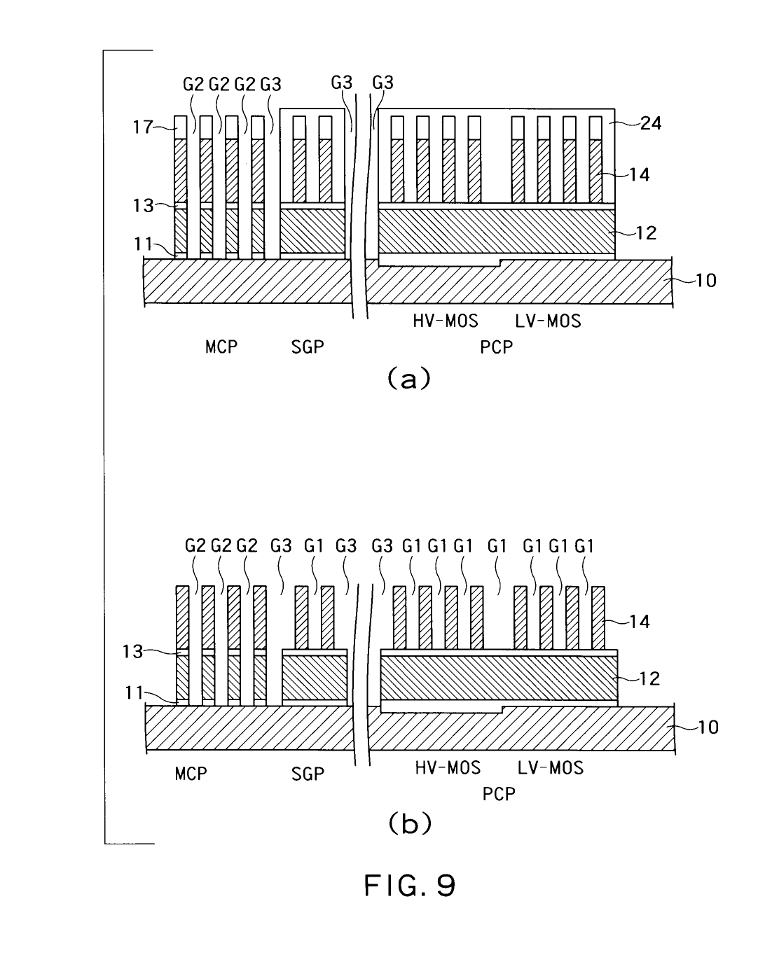

As shown in FIG. 9A, with the mask pattern 34 as masks, the IPD film 13, the floating gate electrode 12, and the gate insulating film 11 are then etched by RIE.

The grooves G1 are extended downward in the memory cell array portion MCP and grooves G2 extended from the SiN films 17 to the upper surface of the silicon substrate 10 are formed. Each of the memory cells MC is formed by the grooves G2. Since the SiN films 17 and the control gate electrodes 14 integrated in a pillar manner have been already processed with high precision, these are used as masks for etching so that the grooves G2, that is, the memory cell MC can be processed with high precision.

At the same time, in the selective gate portion SGP and the peripheral circuit portion PCP, a groove G3 from the SiN film 17 to the upper surface of the silicon substrate 10 is formed so that the predetermined groove G1 is extended further downward. The gate electrode of each of the transistors T is separated by the groove G3.

As shown in FIG. 9B, the second resist film 24 and the SiN films 17 configuring the mask pattern 34 are removed.

An ion implantation process for forming the diffusion layer K of the memory cells MC and each of the transistors T is performed as a mask of the control gate electrodes 14 and the floating gate electrodes 12.

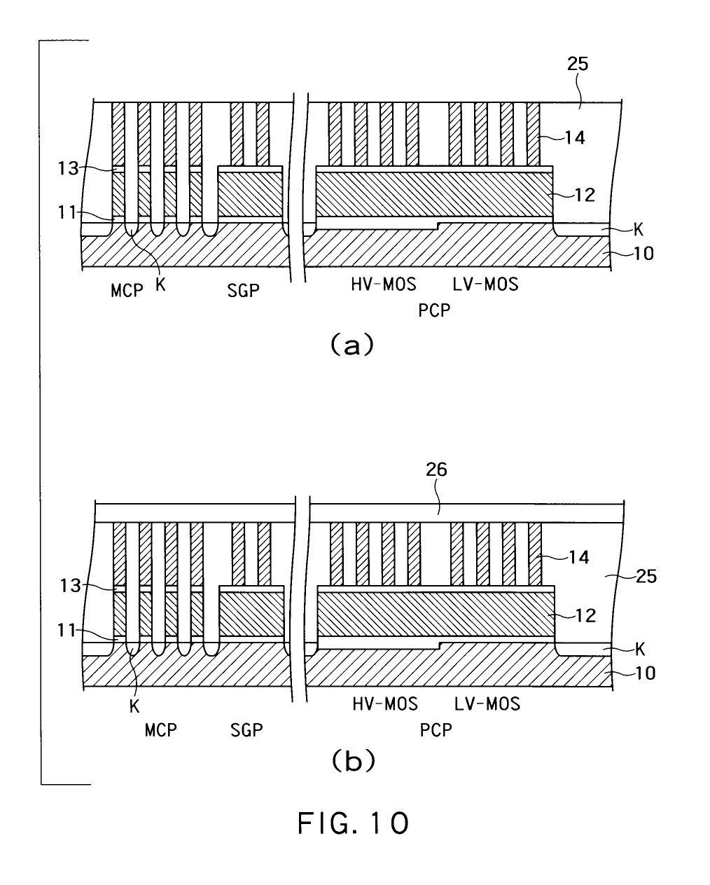

As shown in FIG. 10A, the silicon oxide films 25 such as BPSG (Boro-Phospho Silicate Glass) films are buried into the grooves G2 of the memory cell array portion and the grooves G1 and G3 of the selective gate portion SGP and the peripheral circuit portion PCP.

As shown in FIG. 10B, the SiN film 26 is stacked over the upper surfaces of the silicon oxide film 25 and the control gate electrodes 14.

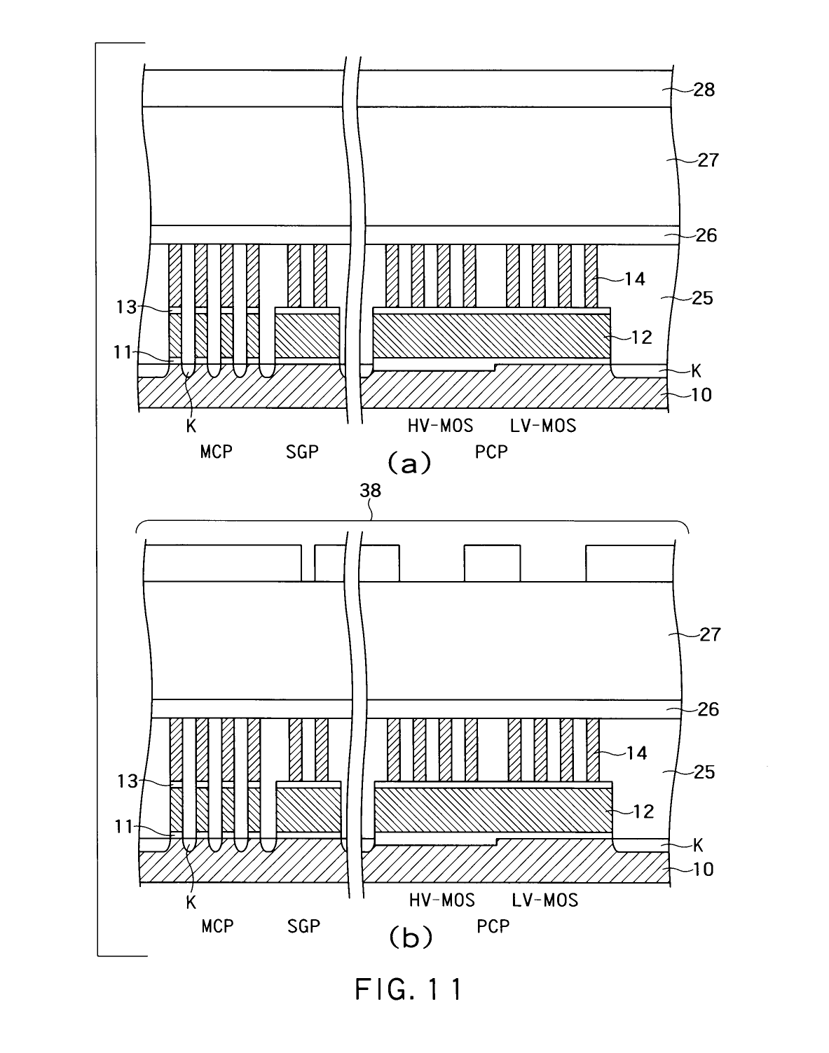

As shown in FIG. 11A, the TEOS film 27 and a third resist film 28 are successively stacked over the SiN film 26.

As shown in FIG. 11B, the third resist film 28 is exposed to form a third resist pattern 38. The resist pattern 38 is a mask for forming contact holes CH.

With the third resist pattern 38 as a mask, in the selective gate portion SGP and the peripheral circuit portion PCP, the TEOS film 27 and the SiN film 26 are etched by RIE (Reactive Ion Etching).

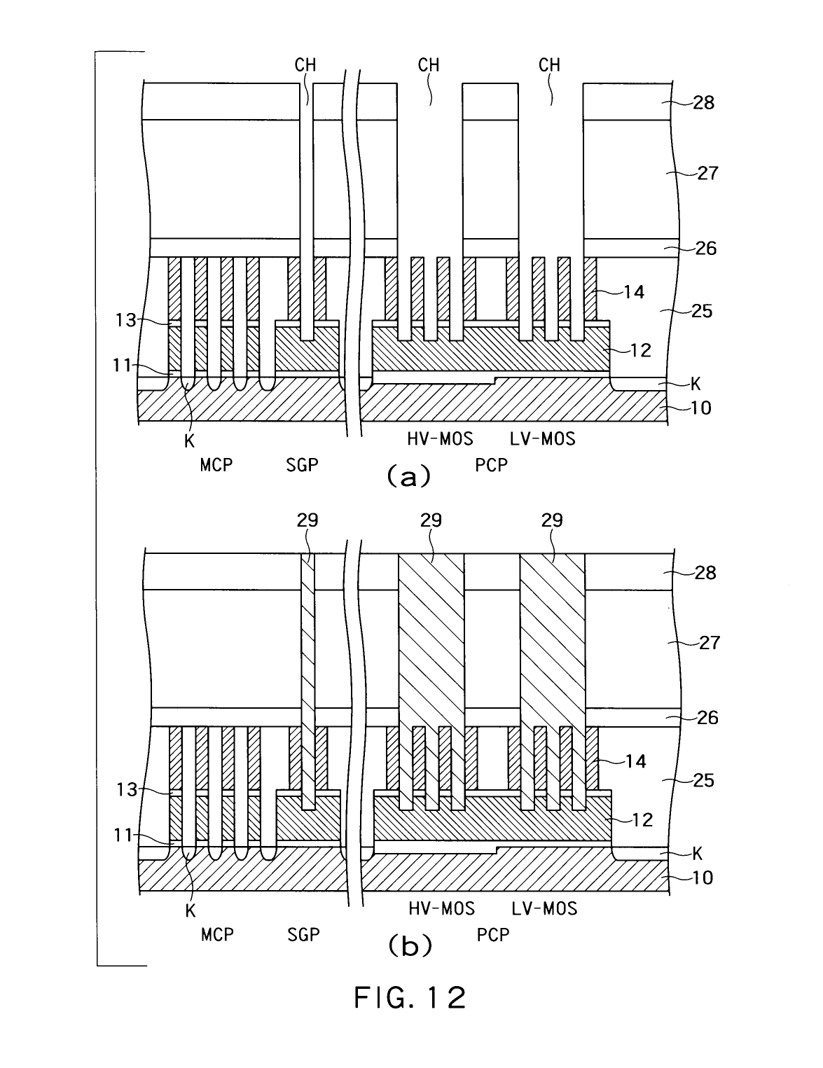

Using the control gate electrodes 14 as masks, the silicon oxide film 25, the IPD film 13, and the floating gate electrode 12 are successively etched, for example, by RIE (Reactive Ion Etching) along the grooves G1 between the control gate electrodes. The contact holes CH in the third resist pattern 38 exposed a top surface of the floating gate electrode 12 shown in FIG. 12A are formed. The control gate electrodes 14 processed with high precision are used as masks for etching so that the contact holes CH can be processed with high precision.

As shown in FIG. 12B, the electrically conductive films are buried into the contact holes CH to form the conductive materials 29. As described above, the electrically conductive films are electrically conductive films having a resistivity lower than that of the control gate electrodes 14 including a polysilicon film and are, tungsten films, for example.

The third resist pattern 38 are then removed to stack interconnect. Finally, the NAND type flash memory according to the present invention can be obtained.

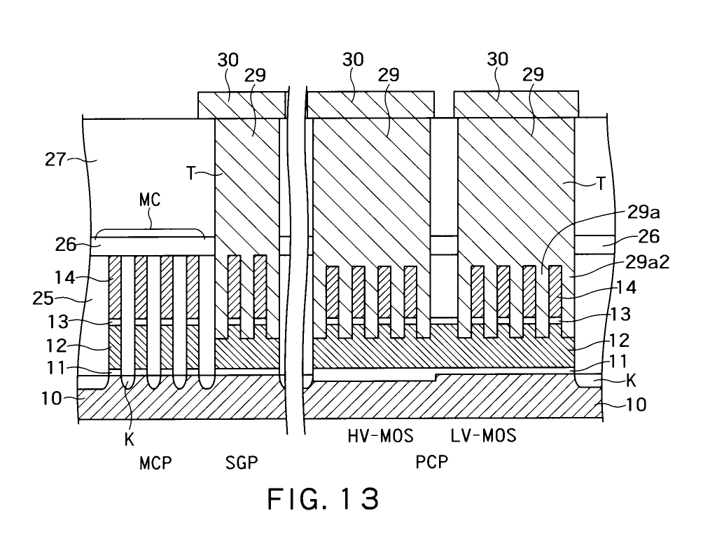

As a modification example of this embodiment, the NAND type flash memory of a structure as shown in FIG. 13 can be provided. In the brief description of the modification example, the shape of the conductive material 29 of each of the transistors is changed. The shape of the conductive material 29 is changed so that the area of the portion of the conductive material 29 contacted with the control gate electrode 14 and the floating gate electrode 12 is increased to reduce the resistance between the control gate electrode 14 and the floating gate electrode 12.

The detail of the modification example will be described with reference to FIG. 13.

As in the embodiment described with reference to FIG. 2, each of the transistors T according to the modification example of this embodiment has the gate insulating film (silicon oxide film) (the second gate insulating film) 11, the floating gate electrode (polysilicon film) 12, the IPD film (interelectrode insulating film) 13, and the control gate electrode (polysilicon film) 14. The silicon oxide film 25 is formed so as to cover the gate insulating film 11, the floating gate electrode 12, the IPD film 13, and the control gate electrode 14 provided in each of the transistors T. The SiN film 26 and the TEOS film 27 are formed over the silicon oxide film 25. The plurality of control gate electrodes 14 provided in each of the transistors T have the same width as that of the control gate electrodes 14 in the memory cell array portion MCP. As in this embodiment, each of the transistors has the conductive material 29 buried into the contact hole penetrated from the control gate electrode 14 through the IPD film 13 to the floating gate electrode 12 along the gap between the adjacent control gate electrodes 14 and electrically connecting the control gate electrode 14 and the floating gate electrode 12.

However, as shown, FIG. 13, in the shape of the conductive material 29 of the modification example, the entire upper surfaces of the control gate electrodes 14, the portions between the control gate electrodes 14, and the entire outer side surfaces of the ends of the control electrodes 14 are covered with the conductive materials 29 including the electrically conductive films. That is, in the modification example, the area of the portion of the conductive material 29 contacted with the control gate electrode 14 is increased. Thus, the resistance between the control gate electrode 14 and the floating gate electrode 12 is reduced, thereby making each of the transistors high-performance.

The NAND type flash memory manufacturing method according to the modification example of this embodiment shown in FIG. 13 is the same as the NAND type flash memory manufacturing method according to this embodiment and the description is omitted.

In the present invention, each of the transistors provided in the NAND type flash memory has the above structure, therefore, each of the transistors can be made high-performance and a plurality of different processes can be integrated into one process. In this way, the manufacturing time and the manufacturing cost of the NAND type flash memory can be reduced.

In the present invention, mask pattern having a uniformly fine pitch are formed once by the side wall remaining method, and using the mask pattern, each of the memory cells and each of the transistors are processed together. Therefore, the fine memory cells can be processed with higher precision.

Additional advantages and modifications will readily occur to those skilled in the art.

Therefore, the invention in its broader aspects is not limited to the specific details and representative embodiments shown and described herein.

Accordingly, various modifications may be made without departing from the spirit or scope of the general inventive concepts as defined by the appended claims and their equivalents.

1. A manufacturing method of a non-volatile memory semiconductor device which has a first region having memory cells and a second region having transistors, comprising:
in the first region and the second region will be formed,
stacking a gate insulating film layer, a floating gate electrode layer, an interelectrode insulating film layer, a control gate electrode layer, and a first mask layer, on a silicon substrate, sequentially; and
etching the control gate electrode layer to expose a surface of the interelectrode insulating film layer by using the first mask as mask, in order to form control gate electrodes having the same width with width of the memory cell, the first mask comprising a line portion having a width corresponding to the width of the memory cell;
in the first region,
etching the interelectrode insulating film layer and the floating gate electrode layer by using the first mask as mask; and
in the second region,
forming a third mask covering at a transistor unit determining a predetermined number of the control gate electrodes as the transistor unit;
etching the interelectrode insulating film layer and the floating gate electrode layer by using the third mask as a mask;
removing the first mask and the third mask;
in the first region and the second region,
forming an interlayer insulating film;
etching the interlayer insulating film and, etching the interelectrode insulating film and the upper portion of the floating gate electrode in the transistor unit to form a contact hole; and
burying a conductive material into the contact hole, the conductive material making the control gate electrodes and the floating gate electrodes electrically conducts to form a gate electrode in which the control gate electrodes and the floating gate electrodes are electrically integrated.

2. The manufacturing method of the non-volatile memory semiconductor device according to claim 1, wherein an electrically conductive film having a resistivity lower than that of the material configuring the control gate electrodes is buried as the conductive material into the contact hole.

3. The manufacturing method of the non-volatile memory semiconductor device according to claim 1, wherein in the first region, the interelectrode insulating film layer and the floating gate electrode layer are etched by using the first mask as a mask, after the third mask is formed in the second region.

4. The manufacturing method of the non-volatile memory semiconductor device according to claim 3, wherein the interelectrode insulating film layer and the floating gate electrode layer are etched, by using the first mask as mask in the first region, and by using the third mask as a mask in the second region.

5. The manufacturing method of the non-volatile memory semiconductor device according to claim 1, wherein the first mask is formed by:
stacking a side wall film layer so as to cover the upper surface and the side surface of a film of a forming mask film on the control gate electrode layer;
remaining only portions of the side wall film on both sides of the forming mask film by etching the side wall film; and
removing portions of the forming mask film between the portions of the side wall film.

6. The manufacturing method of the non-volatile memory semiconductor device according to claim 5, wherein the forming mask film is formed by:
stacking the forming mask film on the control gate electrode layer;
forming a first resist pattern on the forming mask film;
etching the forming mask film to form a pattern by using the first resist pattern as a mask;
removing the first resist pattern; and
selectively slimming the forming mask film.

7. The manufacturing method of the non-volatile memory semiconductor device according to claim 6, further comprising, forming an SOG film on the forming mask film.

8. A non-volatile memory semiconductor device comprising:
a memory cell array portion having memory cells, and a transistor region portion having transistors,
wherein each of the memory cells has a first gate insulating film disposed on a silicon substrate, a first floating gate electrode disposed on the first gate insulating film, a first ineterelectrode insulating film disposed on the first floating gate electrode, and a first control gate electrode disposed on the first interelectrode insulating film,
each of the transistors having a second gate insulating film disposed on the silicon substrate and a gate electrode disposed on the second gate insulating film,
the gate electrode having a second floating gate electrode formed on the second gate insulating film, a second interelectrode insulating film formed on the second floating gate electrode, second control gate electrodes formed on the second interelectrode insulating film, and a conductive material,
wherein the second control gate electrodes of the gate electrode having the same width as that of the first control gate electrode of the memory cell, and
the conductive material being buried into a contact hole penetrated the second interelectrode insulating film and the second floating gate electrode disposed between a pair of adjacent second control gate electrodes so that the gate electrode are formed by the second floating gate electrode, the second control gate electrodes, and the conductive material.

9. The non-volatile memory semiconductor device according to claim 8, wherein the first floating gate electrode and the second floating gate electrode, the first interelectrode insulating film and the second interelectrode insulating film, and, the first control gate electrode and the second control gate electrode are made of the same material and disposed on the same layer, respectively.

10. The non-volatile memory semiconductor device according to claim 8, wherein a distance between the second control gates is equal to a distance between the pair of adjacent first control gate electrodes.

11. The non-volatile memory semiconductor device according to claim 8, wherein the second floating gate electrode has a width larger than a width of the first floating gate electrode.

12. The non-volatile memory semiconductor device according to claim 8, wherein the conductive material includes an electrically conductive film, the electrically conductive film having a resistivity lower than that of the material configuring the second control gate electrode.

13. The non-volatile memory semiconductor device according to claim 12, wherein the electrically conductive film is a tungsten film.

14. The non-volatile memory semiconductor device according to claim 8, wherein the conductive material has a conductive portion between the second control gate electrodes, a bottom of the conductive portion contacting to the second floating gate electrode.

15. The non-volatile memory semiconductor device according to claim 8, wherein an interlayer insulating film is disposed above the second control gate electrodes, the conductive material being penetrated through the interlayer insulating film.

16. The non-volatile memory semiconductor device according to claim 8, wherein the conductive material covers the upper surfaces of the second control gate electrodes, the portions between the second control gate electrodes, and the outer side surfaces of the second control gate electrodes outward of the second control gate electrodes, in the gate electrode.

17. The non-volatile memory semiconductor device according to claim 8, wherein the conductive material has a plurality of conductive portions between the second control gate electrodes.

18. The non-volatile memory semiconductor device according to claim 17, wherein the conductive material further comprises an outermost conductive portion on the outside of the conductive portion, the outermost conductive portion covering the outer side surfaces of the second control gate electrodes.

19. The non-volatile memory semiconductor device according to claim 17, wherein the numbers of the conductive materials provided in each of at least two of the transistors are different.
